(19) United States
(12) Patent Application Publication
(10) Pub. No.: US 2025/0210110 A1
(43) Pub. Date: Jun. 26, 2025

(54) MEMORY DEVICE

(71) Applicant: Kioxia Corporation, Tokyo (JP)

(72) Inventor: Yasuhiro UCHIYAMA, Yokkaichi (JP)

(73) Assignee: Kioxia Corporation, Tokyo (JP)

(21) Appl. No.: 19/073,142

(22) Filed: Mar. 7, 2025

Related U.S. Application Data
(63) Continuation of application No. PCT/JP2022/034724, filed on Sep. 16, 2022.

(51) Int. Cl. G11C 16/08; G11C 16/04

(52) U.S. Cl. CPC G11C 16/08; G11C 16/0483

(57) ABSTRACT

Each of first, second, and third string has one end coupled to a first interconnect and another end coupled to a second interconnect. The first, second, and the third strings include first, second, and third memory cell transistor, respectively. A first power supply line is coupled to a gate of the first memory cell transistor via a first transistor and coupled to a gate of the second memory cell transistor via a second transistor. A second power supply line is coupled to a gate of the third memory cell transistor and applies a voltage different from that of the first power supply line during data erasing.

### CROSS-REFERENCE TO RELATED APPLICATION

This application is a Continuation Application of PCT Application No. PCT/JP2022/034724, filed Sep. 16, 2022, the entire contents of which are incorporated herein by reference.

### FIELD

Embodiments relate generally to a memory device.

### BACKGROUND

A memory device in which memory cells are three-dimensionally arranged is known. The memory device is required to have a smaller area.

### BRIEF DESCRIPTION OF THE DRAWINGS

FIG. 1 shows an example of components of a memory device according to a first embodiment and coupling of the components.

FIG. 2 shows types of blocks according to the first embodiment.

FIG. 3 shows components of a single block of the memory device according to the first embodiment and coupling of the components.

FIG. 4 shows voltages output from the voltage generator of the first embodiment.

FIG. 5 shows components of a driver according to the first embodiment and coupling of the components.

FIG. 6 shows components of a row decoder according to the first embodiment and coupling of the components.

FIG. 7 shows a cross-sectional structure of a part of a memory cell array of the memory device of the first embodiment, and shows a structure along the yz plane.

FIG. 8 shows a concentration distribution of some impurities in the memory device of the first embodiment.

FIG. 9 shows a concentration distribution of some impurities in the memory device of the first embodiment.

FIG. 10 shows voltages applied to some interconnects during data erasing in the memory device of the first embodiment.

FIG. 11 shows voltages applied to some interconnects during data erasing in the memory device of the first embodiment along time.

FIG. 12 shows voltages applied to some interconnects during data writing in the memory device of the first embodiment.

FIG. 13 shows voltages applied to some interconnects during data reading in the memory device of the first embodiment.

FIG. 14 shows voltages applied to some interconnects during data erasing in the memory device according to a modification of the first embodiment.

FIG. 15 shows voltages applied to some interconnects during data writing in the memory device according to a modification of the first embodiment.

FIG. 16 shows voltages applied to some interconnects during data reading in the memory device according to a modification of the first embodiment.

### DETAILED DESCRIPTION

In general, according to one embodiment, a memory device includes a first interconnect, a second interconnect, a first string, a second string, a first power supply line, a third string, and a second power supply line. The first string has one end coupled to the first interconnect and another end coupled to the second interconnect, and includes a first memory cell transistor. The second string has one end coupled to the first interconnect and another end coupled to the second interconnect, and includes a second memory cell transistor. The first power supply line is coupled to a gate of the first memory cell transistor via a first transistor and coupled to a gate of the second memory cell transistor via a second transistor. The third string has one end coupled to the first interconnect and another end coupled to the second interconnect, and includes a third memory cell transistor. The second power supply line is coupled to a gate of the third memory cell transistor and applies a voltage different from that of the first power supply line during data erasing.

Embodiments will now be described with reference to the figures. In order to distinguish components having substantially the same function and configuration in an embodiment or over different embodiments from each other, an additional numeral or letter may be added to the end of each reference numeral or letter. For an embodiment subsequent to an embodiment that has already been described, the description will concentrate mainly on the matters that constitute a difference from the already described embodiment. The entire description of a particular embodiment applies to another embodiment unless an explicit mention is made otherwise, or an obvious elimination is involved.

The figures are schematic, and the relation between the thickness and the area of a plane of a layer and the ratio of thicknesses of layers may differ from those in actuality. Accordingly, the specific thicknesses and/or dimensions may be determined in view of the description to be given below. The figures may include components which differ in relations and/or ratios of dimensions in different figures.

The specification and the claims, when mentioning that a particular (first) component is “coupled” to another (second) component, intend to cover both the form of the first component directly coupled to the second component and the form of the first component coupled to the second component via one or more components which are always or selectively conductive. Descriptions will be made using a xyz orthogonal coordinate system. In the descriptions below, the description “bottom” and “down” and their derivatives and related words refer to the position of a smaller coordinate on the z axis, and the description “top” and “up” and their derivatives and related words refer to the position of a larger coordinate on the z axis.

### 1. First Embodiment

### 1.1. Configuration (Structure)

### 1.1.1. Memory Device

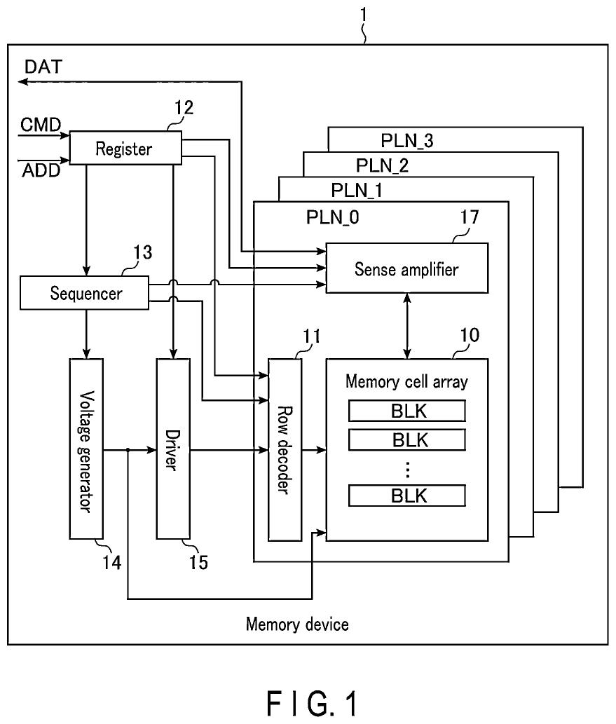

FIG. 1 shows an example of components of a memory device 1 according to a first embodiment and coupling of the components. The memory device 1 is a device that stores data using a memory cell. The memory device 1 is controlled by an external memory controller. The memory device 1 operates based on command CMD and address information ADD received, for example, from the memory controller. The memory device 1 receives data DAT to be written and outputs data stored in the memory device 1.

As shown in FIG. 1, the memory device 1 includes components such as a plurality of planes PLN, for example, four planes PLN_0, PLN_1, PLN_2, and PLN_3, a register 12, a sequencer 13, a voltage generator 14, and a driver 15.

Each of the planes PLN is a set of a plurality of components. The plane PLN is a unit of a target of data writing and data reading (memory area). The planes PLN_0 to PLN_3 can operate independently of each other. Each of the planes PLN includes the same set of components and includes a memory cell array 10, a row decoder 11, and a sense amplifier 17.

The register 12 is a circuit that holds the command CMD and the address information ADD received by the memory device 1. The command CMD instructs the sequencer 13 to perform various operations including data reading, data writing, and data erasing. The address information ADD designates an access target in the memory cell array 10.

The sequencer 13 is a circuit that controls the entire operation of the memory device 1. The sequencer 13 controls the row decoder 11, the driver 15, and the sense amplifier 17 based on the command CMD received from the register 12 to execute various operations including data reading, data writing, and data erasing.

The voltage generator 14 is a circuit that generates a plurality of voltages having different magnitudes. The voltage generator 14 receives a power supply voltage from the outside of the memory device 1 and generates the plurality of voltages from the power supply voltage. The generated voltage is supplied to components such as the memory cell array 10 and the driver 15.

The driver 15 is a circuit that applies various voltages necessary for the operation of the memory device 1 to some components. The driver 15 receives the plurality of voltages from the voltage generator 14 and supplies a selected one of the plurality of voltages to one or more row decoders 11.

The memory cell array 10 is a set of arranged memory cells. The memory cell array 10 includes a plurality of memory blocks (blocks) BLK. Each of the blocks BLK includes a plurality of memory cell transistors MT (not shown). Interconnects such as a word line WL (not shown) and a bit line BL (not shown) are also located in the memory cell array 10.

The row decoder 11 is a circuit for selecting a block BLK. The row decoder 11 transfers the voltage supplied from the driver 15 to a single block BLK selected based on the block address received from the register 12.

The sense amplifier 17 is a circuit that outputs a signal based on data stored in the memory cell array 10. The sense amplifier 17 senses the state of the memory cell transistor MT and generates read data or transfers write data to the memory cell transistor MT based on the sensed state. The sense amplifier 17 also applies a voltage having a magnitude based on the operation to the bit line BL during data reading and data writing.

### 1.1.2. Block Type

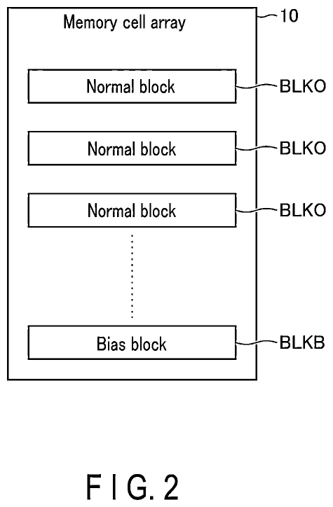

FIG. 2 shows types of blocks according to the first embodiment. FIG. 2 shows a memory cell array 10 of a single plane PLN. The following description applies to the memory cell array 10 of each of the planes PLN.

As shown in FIG. 2, the blocks BLK in the memory cell array 10 in the single plane PLN includes blocks BLK of a normal type and at least a single bias block BLKB. The normal block BLK is used for storing data, and may be hereinafter referred to as a normal block BLKO.

As will be described later, the bias block BLKB has the same configuration as the normal block BLK, that is, components and couplings of the components. On the other hand, the bias block BLKB is not used for storing data, and applies and/or transfers a voltage to a certain element.

### 1.1.3 Circuit Configuration of Memory Cell Array

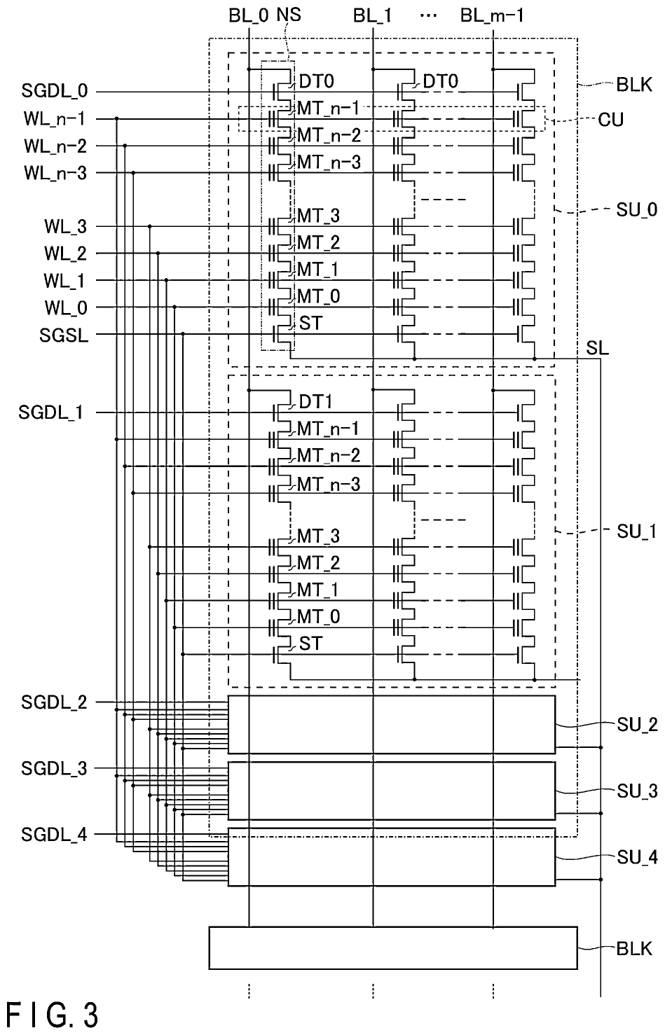

FIG. 3 shows components of a single block BLK of the memory device according to the first embodiment, and coupling among the components. A plurality of blocks BLK, for example, all of the blocks BLK, includes the components and coupling that are shown in FIG. 3. Both the normal block BLK and the bias block BLKB include the components and couplings shown in FIG. 3.

The block BLK includes a plurality of string units SU. FIG. 3 shows an example of five string units SU_0 to SU_4.

As shown in FIG. 3, each of m bit lines BL_0 to BL_m-1 is coupled to a single NAND string NS from each of the string units SU_0 to SU_4 in each of the blocks BLK, where m is a positive integer. Each of the bit lines BL is shared by all of the blocks BLK in each of the planes PLN, that is, common to all of the blocks BLK in each of the planes PLN.

Each of the NAND strings NS includes a single select gate transistor ST, n memory cell transistors MT, and a single select gate transistor DT (i.e., DT0, DT1, DT2, DT3, or DT4), where n is a positive integer. The memory cell transistor MT is an element that includes a control gate electrode and a charge storage film insulated from the periphery, and stores data based on a charge amount in the charge storage film in a non-volatile manner. The select gate transistor ST, the memory cell transistors MT, and the select gate transistor DT are coupled in series in this order between a source line SL and a single bit line BL. The source line SL is shared by all of the blocks BLK in each of the planes PLN, that is, common to all of the blocks BLK in each of the planes PLN.

A plurality of NAND strings NS respectively coupled to a plurality of different bit lines BL configure a single string unit SU. In each of the string units SU, the control gate electrodes of the memory cell transistors MT_0 to MT_n-1 are respectively coupled to word lines WL_0 to WL_n-1. A set of memory cell transistors MT that share a word line WL in a single string unit SU is referred to as a cell unit CU.

The select gate transistors DT0 to DT4 respectively belong to the string units SU_0 to SU_4. In FIG. 3, the select gate transistors DT2, DT3, and DT4 are not shown. A gate of the select gate transistor DT0 of each of the plurality of NAND strings NS of the string unit SU_0 is coupled to a select gate line SGDL0. Similarly, gates of the select gate transistor DT1, DT2, DT3, or DT4 of each of the plurality of NAND strings NS of each of the string units SU_1, SU_2, SU_3, and SU_4 are coupled to select gate lines SGDL_1, SGDL_2, SGDL_3, or SGDL_4, respectively.

A gate of the select gate transistor ST is coupled to a select gate line SGSL.

### 1.1.4. Voltage Generator

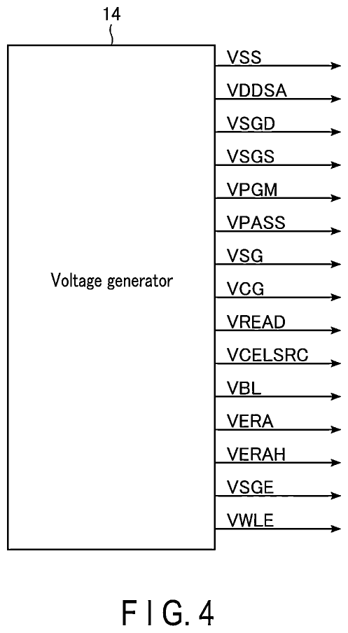

FIG. 4 shows voltages output from the voltage generator of the first embodiment. As shown in FIG. 4, the voltage generator 14 generates and outputs a ground voltage VSS, a power supply voltage VDDSA, a program selection voltage VSGD, a program selection voltage VSGS, a program voltage VPGM, a program pass voltage VPASS, a read selection voltage VSG, a read voltage VCG, a read pass voltage VREAD, a read bias voltage VCELSRC, a read bias voltage VBL, an erase voltage VERA, an erase voltage transfer voltage VERAH, an erase selection voltage VSGE, and an erase bias voltage VWLE from voltages supplied to the memory device 1.

The ground voltage VSS is set to, for example, 0 V. The power supply voltage VDDSA is higher than 0 V.

The program selection voltage VSGD is higher than 0 V. While the program selection voltage VSGD is being applied to the gate of the select gate transistor DT coupled to the bit line BL receiving a certain low or voltage high voltage used in data writing, the select gate transistor DT remains off and on, respectively.

The program selection voltage VSGS is higher than 0 V. While the program selection voltage VSGS is being applied to the gate of the select gate transistor ST, the select gate transistor ST remains off even if a voltage of more than 0 V used in data writing is applied to the source line SL.

The program voltage VPGM is higher than 0 V and has a variable magnitude. The program voltage VPGM has a magnitude that allows electrons to move into a charge storage film of the memory cell transistor MT while being applied to the gate electrode of the memory cell transistor MT.

The program pass voltage VPASS is lower than the program voltage VPGM. The program pass voltage VPASS has a magnitude to turn on the memory cell transistor MT to which no data is written and to prevent electrons from moving into the charge storage film of the memory cell transistor MT to which no data is written.

The read selection voltage VSG is higher than 0 V. The read selection voltage VSG has a magnitude that allows a current used in data reading to flow through the select gate transistors DT and ST while being applied to the gates of the select gate transistors DT and ST.

The read voltage VCG is higher than 0 V and has a variable magnitude determined based on the type of data reading.

The read pass voltage VREAD has a magnitude that maintains the memory cell transistor MT on regardless of the state while being applied to the gate of the memory cell transistor MT, and is higher than the read voltage VCG.

The read bias voltage VCELSRC is higher than 0 V. The read bias voltage VBL is higher than the read bias voltage VCELSRC.

The erase voltage VERA is higher than 0 V and higher than the program voltage VPGM and the read pass voltage VREAD. The erase voltage VERA has a magnitude that allows holes to be supplied to the semiconductor in the NAND string NS while being applied to the source line SL and/or the bit line BL.

The erase voltage transfer voltage VERAH is higher than the erase voltage VERA. The erase voltage transfer voltage VERAH has a magnitude that enables the memory cell transistor MT and the select gate transistors DT and ST receiving the erase voltage transfer voltage VERAH at the gate to transfer the erase voltage VERA.

The erase selection voltage VSGE is higher than 0 V. The erase selection voltage VSGE has a magnitude that enables gate induced drain leakage (GIDL) to occur in the select gate transistors ST and/or DT while the erase selection voltage VSGE is being applied to the select gate transistors ST and/or DT, respectively, while being applied to the source line SL and/or the bit line BL.

The erase bias voltage VWLE has a magnitude that allows the holes to move into a charge storage film of the memory cell transistor MT while being appled to the gate of the memory cell transistor MT. The erase bias voltage VWLE has, for example, the same magnitude as the ground voltage VSS, and is, for example, 0 V. The erase bias voltage VWLE may be less than 0 V.

### 1.1.5. Driver

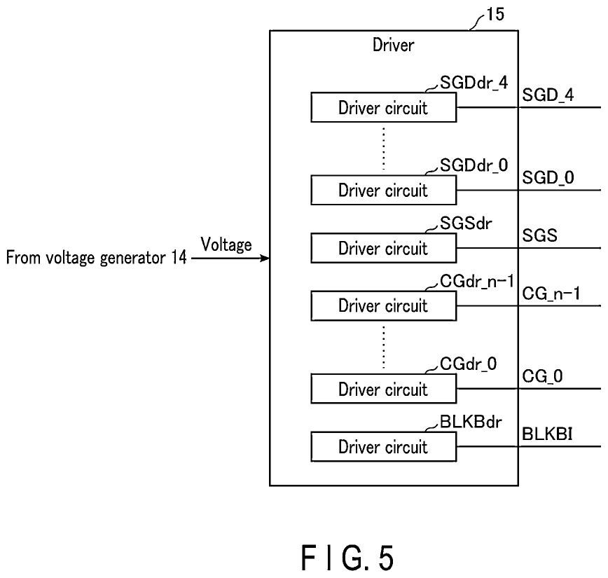

FIG. 5 shows components of a driver according to the first embodiment and coupling of the components.

As shown in FIG. 5, the driver 15 includes the same number of driver circuits SGDdr (SGDdr_0 to SGDdr_4) as the number of string units SU included in a single block BLK, and a driver circuit SGSdr, and the driver 15 includes the same number of driver circuits CGdr (CGdr_0 to CGdr_n-1) as the number of word lines WL included in a single NAND string NS, and a driver circuit BLKBdr.

The driver circuits SGDdr_0 to SGDdr_4 receive the ground voltage VSS, the program selection voltage VSGD, the read selection voltage VSG, and the erase selection voltage VSGE from the voltage generator 14. The driver circuits SGDdr_0 to SGDdr_4 supply one of the received voltages indicated by the sequencer 13 to interconnects SGD_0 to SGD_4, respectively.

The driver circuits CGdr_0 to CGdr_n-1 receive the program voltage VPGM, the program pass voltage VPASS, the read voltage VCG, the read pass voltage VREAD, and the erase bias voltage VWLE from the voltage generator 14. The driver circuits CGdr_0 to CGdr_n-1 supply one of the received voltages instructed by the sequencer 13 to interconnects CG_0 to CG_n-1, respectively.

The driver circuit SGSdr receives the program selection voltage VSGS, the read selection voltage VSG, and the erase selection voltage VSGE from the voltage generator 14. The driver circuit SGSdr supplies one of the received voltages indicated by the sequencer 13 to an interconnect SGS.

The driver circuit BLKBdr receives the erase voltage transfer voltage VERAH from the voltage generator 14. The driver circuit BLKBdr supplies the erase voltage transfer voltage VERAH to the interconnect BLKBI based on an instruction from the sequencer 13.

### 1.1.6. Block Decoder

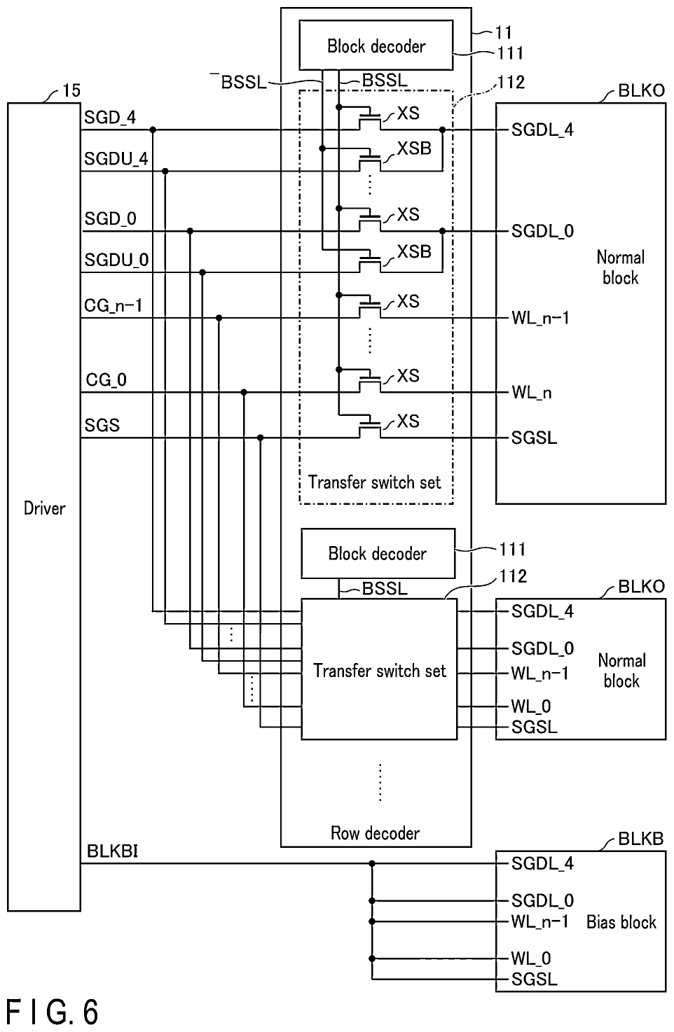

FIG. 6 shows components of a row decoder according to the first embodiment and coupling of the components. FIG. 6 also shows blocks BLK.

The row decoder 11 includes the same number of block decoders 111 as the number of normal blocks BLKO and the same number of transfer switch sets 112 as the number of normal blocks BLKO.

The block decoder 111 is a circuit that decodes the address information ADD, outputs a block selection signal BSS on an interconnect BSSL and outputs a signal ^{_}BSS on an interconnect ^{_}BSSL based on the decoding result. The signal^{_}BSS has logic of inversion of logic of the block selection signal BSS.

Each of the block decoders 111 is associated with a single normal block BLKO. Each of the block decoders 111 performs control for bringing the associated normal block BLKO into a selected state. When the address information ADD specifies the normal block BLKO with which the block decoder 111 is associated, the block decoder outputs an asserted block selection signal BSS.

Each of the transfer switch sets 112 is a set of a plurality of transfer switches XS and a plurality of transfer switches XSB. Each of the transfer switch sets 112 is associated with a single normal block BLKO. Each of the transfer switch sets 112 turns into a state where the normal block BLKO associated with itself is selected based on the block selection signal BSS. Each of the transfer switches XS is, for example, an n-type MOSFET. The four transfer switches XS are coupled between the interconnects SGD_0 to SGD_4 and the select gate lines SGDL_0 to SGDL_4, respectively. The n transfer switches XS are coupled between the interconnects CG_0 to CG_n-1 and the word lines WL_0 to WL_n-1, respectively. A single transfer switch XS is coupled between the interconnect SGS and the select gate line SGSL. Each of the transfer switches XS receives the block selection signal BSS at its own gate.

Each of the transfer switches XSB is, for example, an n-type MOSFET. The four transfer switches XSB are coupled between interconnects SGDU_0 to SGDU_4 and the select gate lines SGDL_0 to SGDL_4, respectively. The interconnect SGDU_0 to SGDU_4 receive the ground voltage Vss from the voltage generator 14 or from the voltage generator 14 via the driver 15. Each of the transfer switches XSB receives the signal BSS at its own gate.

When a certain block selection signal BSS is asserted, the transfer switch XS that receives the block selection signal BSS is turned on. As a result, the voltages of the interconnects SGD, CG, and SGS are transferred to the select gate line SGDL, the word line WL, and the select gate line SGSL of the selected block BLK, respectively. On the other hand, while the block BLK is not selected, the signal BSS for the block BLK is asserted. Therefore, in this unselected block BLK, the transfer switch XSB is turned on. Therefore, the select gate lines SGDL_0 to SGDL_4 receive the ground voltage VSS via the interconnects SGDU_0 to SGDU_4, respectively.

As described above, the normal block BLKO is coupled to the driver 15 via the row decoder 11. On the other hand, the bias block BLKB is coupled to the driver 15 without interposing the row decoder 11. That is, a set of the select gate line SGDL, the word lines WL, and the select gate line SGSL of the bias block BLKB is coupled to the interconnect BLKBI coupled to the driver 15.

### 1.1.5. Memory Cell Array

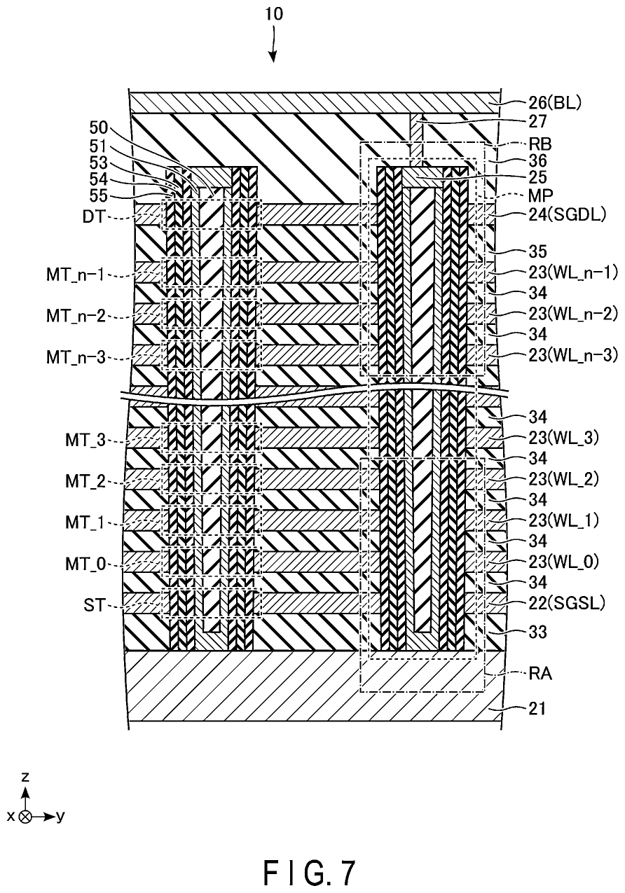

FIG. 7 shows a cross-sectional structure of a part of a memory cell array of the memory device of the first embodiment, and shows a structure along the yz plane. As shown in FIG. 7, the memory cell array 10 includes conductors 21 and 22, n conductors 23, conductors 24 and 27, and insulators 33 to 36. The insulators 33 to 36 contain or are made of silicon oxide, for example.

The conductor 21 extends along the xy plane and has a plate shape. The conductor 21 functions as at least a part of the source line SL. The conductor 21 contains or is made of phosphorus-doped silicon, for example, and has an n-type conductivity type.

The insulator 33 is located on the upper surface of the conductor 21.

The conductor 22 is located on the upper surface of the insulator 33. The conductor 22 extends along the xy plane and has a plate shape. The conductor 22 functions as at least a part of the select gate line SGSL. The conductor 22 contains or is made of tungsten, for example.

The plurality of insulators 34 and the plurality of conductors 23 are alternately positioned one by one along the z axis on the upper surface of the conductor 22. Therefore, the conductors 23 are arranged along the z axis at intervals. The insulators 34 and the conductors 23 extend along the xy plane and have a plate shape. The plurality of conductors 23 functions as at least parts of the word lines WL_0 to WL_n-1 in order from the conductor 21 side. The conductors 23 contain or are made of tungsten, for example.

The insulator 35 is located on the upper surface of the uppermost conductor 23.

The conductor 24 is located on the upper surface of the insulator 35. The conductor 24 functions as at least a part of one of the select gate lines SGDL_0 to SGDL_4. The conductor 24 contains or is made of tungsten.

The insulator 36 is located on the upper surface of the conductor 24.

The conductor 26 is located on the upper surface of the insulator 36. The conductor 26 has a linear shape and extends along the y axis. The conductor 26 functions as at least a part of a single bit line BL. The conductors 26 are also provided on the yz plane different from the yz plane shown in FIG. 7, and thus, the conductors 26 are arranged at intervals along the x axis. The conductor 26 contains or is made of copper, for example.

A memory pillar MP extends along the z axis and has a column shape. The memory pillar MP is located in a stacked structure including the insulators 33 to 36 and the conductors 22 to 24, and penetrates or passes through the insulators 33 to 36 and the conductors 22 to 24. The upper surface of the memory pillar MP is positioned above the uppermost conductor 24. The lower surface of the memory pillar MP is in contact with the conductor 21. A portion where the memory pillar MP and the conductor 22 are in contact with each other functions as the select gate transistor ST. A portion where the memory pillar MP and the single conductor 23 are in contact with each other functions as a single memory cell transistor MT. A portion where the memory pillar MP and the conductor 24 are in contact with each other functions as a single select gate transistor DT.

The memory pillar MP includes, for example, a core 50, a semiconductor 51, a tunnel insulator 53, a charge storage film 54, a block insulator 55, and a conductor 27. The core 50 extends along the z axis and has a column shape. The core 50 is made of an insulator, and contains or is made of silicon oxide, for example.

The semiconductor 51 covers the surface of the core 50. The semiconductor 51 is in contact with the conductor 21 on the lower surface. The semiconductor 51 functions as a channel (current path) of the memory cell transistor MT and the select gate transistors DT and ST. The semiconductor 51 contains or is made of silicon, for example.

The tunnel insulator 53 surrounds the side surface of the semiconductor 51. The tunnel insulator 53 contains or is made of silicon oxide, for example.

The charge storage film 54 surrounds the side surface of the tunnel insulator 53. The charge storage film 54 contains or is made of silicon nitride, for example, silicon nitride.

The block insulator 55 surrounds the side surface of the charge storage film 54. The side surface of the block insulator 55 is surrounded by the conductors 23. The block insulator 55 contains or is made of silicon oxide, for example.

The structure of the memory pillar MP is not limited to the example shown in FIG. 7. For example, a region including the bottom surface of the memory pillar MP may be located in the conductor 21. In this case, a set of the tunnel insulator 53, the charge storage film 54, and the charge storage film 54 is partially opened in the conductor 21. With the material of the conductor 21 located in the opening, the conductor 21 is in contact with the semiconductor 51.

The conductor 25 is located on the upper surfaces of the core 50 and the semiconductor 51. The conductor 25 contains or is made of phosphorus-doped silicon, for example.

A single memory pillar MP and a single conductor 25 are coupled by the conductor 27.

The structure around the structure shown in FIG. 7 may be any structure. For example, the conductor 21 is located above the substrate, and circuits such as the row decoder 11, the driver 15, and/or the sense amplifier 17 are formed in a region including the upper surface of the substrate. The circuit may be provided below the memory pillar MP to be described later on the upper surface of the substrate, or may be provided in a region different from the region below the region where the memory pillar MP is provided on the upper surface of the substrate.

Alternatively, the memory device 1 may include an upper structure obtained by inverting the structure shown in FIG. 7 along the xy plane above the substrate. That is, the memory device 1 includes a substrate and a lower structure including a circuit formed in a region including an upper surface of the substrate. The structure shown in FIG. 7 is formed on another substrate, and a structure in which the formed structure is inverted with respect to the xy plane is joined to the lower structure as the upper structure. Then, the substrate used to form the upper structure is removed.

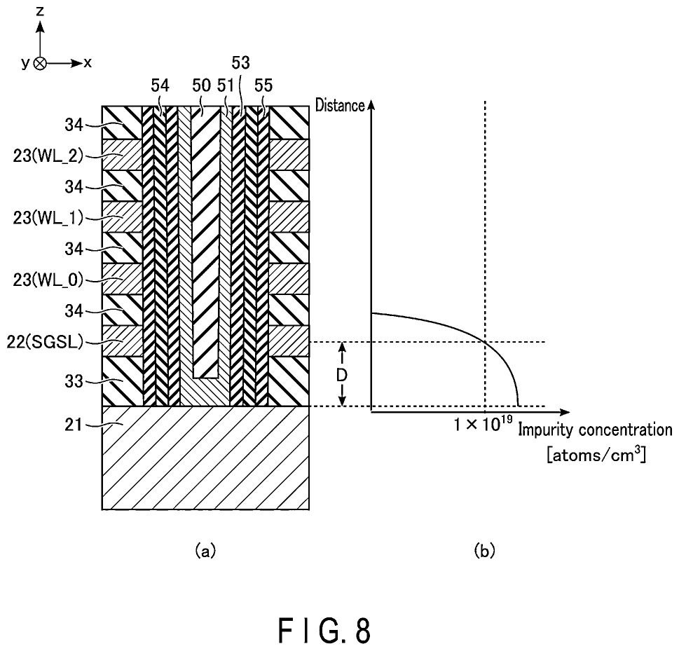

FIG. 8 shows a concentration distribution of some impurities in the memory device of the first embodiment. FIG. 8 shows a region RA shown in FIG. 7 in an enlarged manner in a portion (a). FIG. 8 shows a concentration distribution of impurities contained in the portion (a) of the semiconductor 51 in a portion (b).

As shown in the portion (b), a region including the end of the semiconductor 51 on the side of the conductor 21 is doped with phosphorus as an impurity, for example. Since phosphorus is contained, the region including the end of the semiconductor 51 on the side of the conductor 21 has an n-type conductivity type. The impurity to be doped is not limited to phosphorus. For example, arsenic may be doped.

Phosphorus is distributed as follows, for example. That is, the portion of the semiconductor 51 included in the range of the distance D or less from the interface with the conductor 21 toward the conductor 22 contains phosphorus at a concentration of, for example, 1×10¹⁹ atoms/cm³ or more. A portion of the semiconductor 51 exceeding the distance D from the interface with the conductor 21 toward the conductor 22 contains phosphorus at a concentration lower than 1×10¹⁹ atoms/cm³, for example. The distance D is longer than the distance from the interface between the semiconductor 51 and the conductor 21 to the lower surface of the conductor 22, and shorter than the distance from the interface between the semiconductor 51 and the conductor 21 to the upper surface of the conductor 22.

Due to such a concentration distribution of impurities, the channel of the select gate transistor ST includes a portion where the concentration of phosphorus is 1×10¹⁹ atoms/cm³ or more. As a result, the select gate transistor ST can generate a GIDL current in the semiconductor 51. The GIDL current produces an electron-hole pair. The holes of the generated electron-hole pair can be re-coupled with the electrons taken in the charge storage film 54 by being injected into the charge storage film 54. By the re-coupling, negative charges disappear from the charge storage film 54. The threshold voltage of the memory cell transistor MT decreases due to the disappearance of the negative charge. That is, the data stored in the memory cell transistor MT is erased. Hereinafter, the GIDL current flowing from the source line SL toward the select gate transistor DT may be referred to as an SL-side GIDL current.

In addition, the channel of the select gate transistor ST includes a portion where the concentration of phosphorus is less than 1×10¹⁹ atoms/cm³. As a result, the select gate transistor ST also functions as a switch that controls coupling and uncoupling between the source line SL (the conductor 21) and the memory cell transistor MT_0 in data writing and data reading.

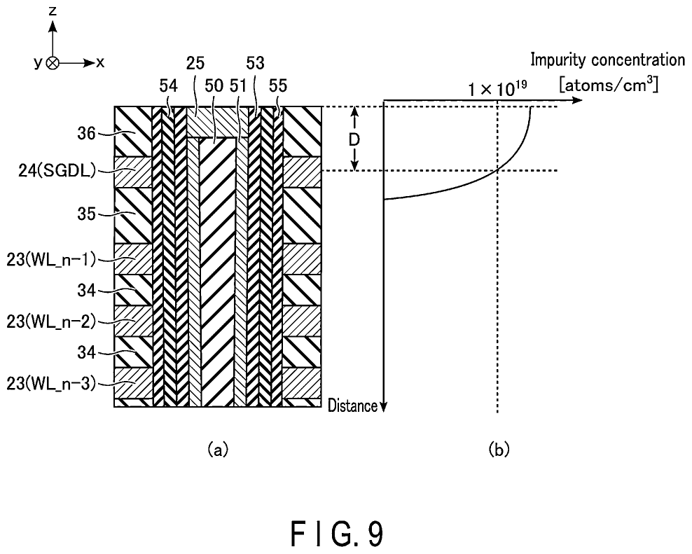

The semiconductor 51 also contains impurities such as phosphorus in the portion of the select gate transistor DT, similarly to the portion of the select gate transistor ST. FIG. 9 shows a concentration distribution of some impurities in the memory device of the first embodiment. FIG. 9 shows a region RB shown in FIG. 7 in an enlarged manner in a portion (a). FIG. 9 shows a concentration distribution of impurities contained in the portion (a) of the semiconductor 51 and the conductor 25 in a portion (b).

As shown in the portion (b), a region including an end on a side (upper side) of the conductor 27 (not shown) of a set of the semiconductor 51 and the conductor 25 is doped with phosphorus as an impurity, for example. Since phosphorus is contained, the region including the end of the set of the semiconductor 51 and the conductor 25 on the side of the conductor 27 has an n-type conductivity type. The impurity to be doped is not limited to phosphorus. For example, arsenic may be doped.

Phosphorus is distributed as follows, for example. That is, the portion of the set of the semiconductor 51 and the conductor 25 included in the range of the distance D or less from the upper surface of the conductor 25 toward the conductor 24 contains phosphorus at a concentration of, for example, 1×10¹⁹ atoms/cm³ or more. A portion of the set of the semiconductor 51 and the conductor 25 exceeding the distance D from the upper surface of the conductor 25 toward the conductor 24 contains phosphorus at a concentration lower than 1×10¹⁹ atoms/cm³, for example. The distance D is longer than the distance from the upper surface of the conductor 25 to the upper surface of the conductor 24 and shorter than the distance from the upper surface of the conductor 25 to the lower surface of the conductor 24.

Due to such a concentration distribution of impurities, the channel of the select gate transistor DT includes a portion where the concentration of phosphorus is 1×10¹⁹ atoms/cm³ or more. As a result, the select gate transistor DT can generate the GIDL current in the semiconductor 51 and the conductor 25. Holes can be generated by the GIDL current. Hereinafter, the GIDL current flowing from the bit line BL toward the select gate transistor DT may be referred to as a BL-side GIDL current.

In addition, the channel of the select gate transistor DT includes a portion where the concentration of phosphorus is less than 1×10¹⁹ atoms/cm³. As a result, the select gate transistor DT also functions as a switch that controls coupling and uncoupling between the bit line BL (the conductor 26) and the memory cell transistor MT_n-1 in data writing and data reading.

### 1.2. Operation

### 1.2.1. Data Erasing

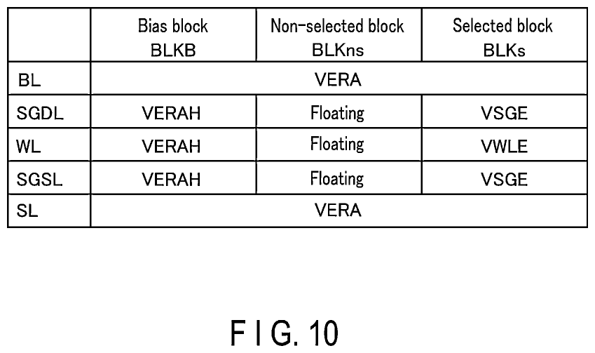

FIG. 10 shows voltages applied to some interconnects during data erasing (data erase operation) in the memory device of the first embodiment. FIG. 10 shows the bias block BLKB, a non-selected block BLKns, and a selected block BLKs. The selected block BLKs is a block BLK subject to data erasing among the normal blocks BLKO. The non-selected block BLKns is a block BLK other than the selected block BLKs among the normal blocks BLKO.

The block decoder 111 coupled with the selected block BLKs is activated, that is, all transfer switches XS in the activated block decoder 111 are on, while the block decoder 111 coupled with the non-selected block BLKns is deactivated, that is, all transfer switches XS in the deactivated block decoder 111 are off.

The source line SL receives the erase voltage VERA by the voltage generator 14 and the driver 15. As described above with reference to FIG. 3, the source line SL is coupled to each of the blocks BLK, that is, the bias block BLKB, the non-selected block BLKns, and the selected block BLKs. Therefore, in any of the bias block BLKB, the non-selected block BLKns, and the selected block BLKs, the source line SL has the potential VERA.

All the select gate lines SGDL (SGDL_0 to SGDL_4), all the word lines WL (WL_0 to WL_n-1), and the select gate line SGSL of the bias block BLKB receive the erase voltage transfer voltage VERAH from the driver 15. Therefore, all the select gate transistors DT, all the memory cell transistors MT, and the select gate transistor ST of the bias block BLKB are on and in a state to be able to transfer the erase voltage VERA.

All the select gate transistors DT, all the memory cell transistors MT, and all the select gate transistors ST of the bias block BLKB are on and in a state of being able to transfer the erase voltage VERA. Therefore, any of the bit lines BL is electrically connected to the source line SL via the NAND string NS that is coupled to the bit line and includes the select gate transistors DT and ST and the memory cell transistors MT that are in a state of being able to transfer the erase voltage VERA. In addition, the source line SL receives the erase voltage VERA. Therefore, each of the bit lines BL receives the erase voltage VERA via the NAND string NS coupled to the bit line BL, and is charged by the erase voltage VERA. During data erasing, each of the bit lines BL does not receive a voltage from the sense amplifier 17 and is not coupled to any other node via the transistor that is on.

The block decoder 111 coupled to any non-selected block BLKns is in an inactive state. Therefore, in each of the non-selected blocks BLKns, all the select gate lines SGDL, all the word lines WL, and the select gate line SGSL are electrically floating. Therefore, the select gate transistors DT and ST and the memory cell transistor MT of the non-selected block BLKns are off.

Since the block decoder 111 coupled to the selected block BLKs is in an active state, the selected block BLKs is in a state of receiving a voltage from each of the driver circuits SGDdr (SGDdr_0 to SGDdr_4). In addition, each of the driver circuits SGDdr outputs the erase selection voltage VSGE. Therefore, each of the select gate lines SGDL receives the erase selection voltage VSGE.

Since the block decoder 111 coupled to the selected block BLKs is in the active state, the selected block BLKs is in a state of receiving a voltage from each of the driver circuits CGdr (CGdr_0 to CGdr_n-1). In addition, each of the driver circuits CGdr_outputs the erase bias voltage VWLE. Therefore, each of the word lines WL receives the erase bias voltage VWLE.

Since the block decoder 111 coupled to the selected block BLKs is in the active state, the selected block BLKs is in a state of receiving a voltage from the driver circuit SGSdr. In addition, the driver circuit SGSdr outputs the erase selection voltage VSGE. Therefore, the select gate line SGSL receives the erase selection voltage VSGE.

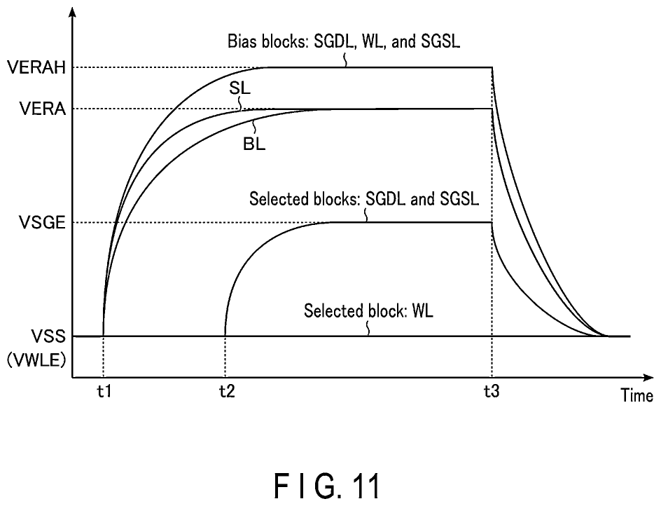

FIG. 11 shows voltages applied to some interconnects during data erasing in the memory device of the first embodiment along time. FIG. 11 shows the bias block BLKB and the selected block BLKs among the bias block BLKB, the non-selected block BLKns, and the selected block BLKs.

As shown in FIG. 11, at the initial time of the range shown in FIG. 11, the ground voltage VSS is applied to all the interconnects.

From time t1, the erase voltage transfer voltage VERAH is applied to the select gate line SGDL, the word line WL, and the select gate line SGSL of the bias block BLKB. In addition, the erase voltage VERA is applied to the source line SL from time t1. The application of the erase voltage VERA may be prior to the application of the erase voltage transfer voltage VERAH. By the application of the erase voltage VERA and the erase voltage transfer voltage VERAH, the voltage of the source line SL is transferred in the bias block BLKB from time t1, whereby the erase voltage VERA is applied to the bit line BL.

From time t2, the erase selection voltage VSGE is applied to the select gate line SGSL of the selected block BLKs. As a result, from time t2, a state in which the erase voltage VERA is applied to the source line SL and the erase selection voltage VSGE is applied to the select gate line SGSL is formed. By such voltage application, the SL-side GIDL current flows from the select gate transistor ST toward the inside of the NAND string NS. The electron-hole pair is generated by the SL-side GIDL current.

In addition, from time t2, a state in which the erase voltage VERA is applied to each of the bit lines BL and the erase selection voltage VSGE is applied to each of the select gate lines SGDL is formed. By such voltage application, the BL-side GIDL current flows from the select gate transistor DT toward the inside of the NAND string NS. The electron-hole pair is generated by the BL-side GIDL current.

Holes generated by the BL-side GIDL current and the SL-side GIDL current move inward (toward the center of the NAND string NS) in the memory cell transistors MT coupled in series in the semiconductor 51. The word line WL of the selected block BLKs continues to receive the erase bias voltage VWLE. Therefore, the holes in the semiconductor 51 are drawn by the erase bias voltage VWLE applied to the word line WL and enter the charge storage film 54. The entered holes re-couple with electrons in the charge storage film 54. By the re-coupling, electrons in the charge storage film 54 disappear, and the amount of electrons in the charge storage film 54 decreases. As a result, the threshold voltage of the memory cell transistor MT of the selected block BLKs decreases, and eventually, the data is erased.

From time t3, the ground voltage VSS is applied to the select gate lines SGDL and SGSL and the word line WL of the bias block BLKB and the select gate lines SGDL and SGSL of the selected block BLKs.

### 1.2.2. Data Writing

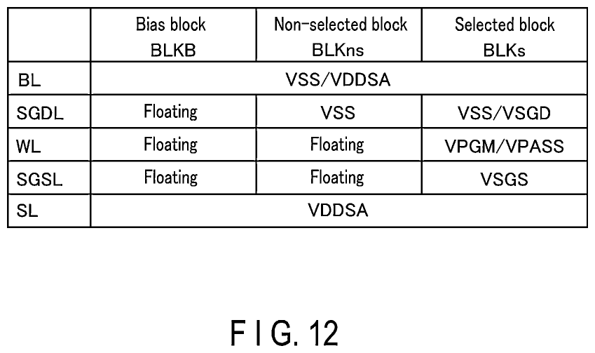

FIG. 12 shows voltages applied to some interconnects during data writing (data write operation) in the memory device of the first embodiment.

During data writing, the driver circuits SGDdr_0 to SGDdr_4 output the program selection voltage VSGD or the ground voltage VSS. Among the five string units SU included in each of the blocks BLK, the string unit SU including the cell unit CU to be accessed by data writing or data reading in the selected block BLKs may be referred to as a selected string unit SUs. The string units SU other than the selected string unit SUs may be referred to as non-selected string units SU. The driver circuit SGDdr coupled to the selected string unit SUs outputs the program selection voltage VSGD. The driver circuit SGDdr coupled to the non-selected string unit SU outputs the ground voltage VSS.

During data writing, the driver circuit CGdrv outputs the program voltage VPGM or the program pass voltage VPASS. The data writing includes a plurality of program loops, and the program voltage VPGM has different magnitudes in different program loops.

During data writing, the driver circuit SGSdr outputs the program selection voltage VSGS.

Each of the bit lines BL receives the ground voltage VSS or the power supply voltage VDDSA by the sense amplifier 17. The bit line BL coupled to the NAND string (selected NAND string) NS including the memory cell transistor MT whose threshold voltage is to be raised by data writing receives the ground voltage VSS. The bit line BL coupled to the NAND string (non-selected NAND string) NS including the memory cell transistor MT whose threshold voltage is not to be raised by data writing receives the power supply voltage VDDSA.

The source line SL receives the power supply voltage VDDSA by the driver 15.

The bias block BLKB is required not to participate in the data writing and not to hinder the data writing in the selected block BLKs. For this purpose, during data reading, each of the select gate lines SGDL, each of the word lines WL, and the select gate line SGSL of the bias block BLKB are electrically floating. This can be performed, for example, by electrically uncoupling the node in the driver circuit BLKBdr from the interconnect BLKBI. Since the select gate lines SGDL and SGSL and the word line WL of the bias block BLKB are electrically floating, the select gate transistors DT and ST and the memory cell transistor MT of the bias block BLKB are off.

The block decoder 111 coupled to any non-selected block BLKns is in an inactive state. Therefore, in each of the non-selected blocks BLKns, each of the select gate lines SGDL receives the ground voltage VSS, and each of the word lines WL and the select gate line SGSL are electrically floating. Therefore, the select gate transistors DT and ST and the memory cell transistor MT of the non-selected block BLKns are off.

On the other hand, the selected block BLKs receives voltages from the driver circuits SGDdr, CGdr, and SGSdr via the block decoder 111 coupled to the selected block BLKs. Therefore, the select gate line SGDL of the selected block BLKs receives the program selection voltage VSGD or the ground voltage VSS. In addition, the word line WL of the selected block BLKs receives the program voltage VPGM or the program pass voltage VPASS. Furthermore, the select gate line SGSL of the selected block BLKs receives the program selection voltage VSGS.

By applying the voltages as described above, data is written to the cell unit CU that is subject to data writing of the selected block BLKs. The select gate transistor DT of the selected NAND string NS is turned on, and electrons are supplied from the bit line BL to the semiconductor 51 of the selected NAND string NS. These electrons are drawn by the program voltage VPGM and injected into the charge storage film 54 of the memory cell transistor MT in the selected NAND string NS and the cell unit CU that is subject to data writing. On the other hand, the select gate transistor DT of the non-selected NAND string NS is not turned on. Therefore, the supply of electrons from the bit line BL to the semiconductor 51 of the non-selected NAND string NS is suppressed. Therefore, injection of electrons into the charge storage film 54 of the memory cell transistor MT in the cell unit CU in the non-selected NAND string NS is suppressed.

### 1.2.2. Data Reading

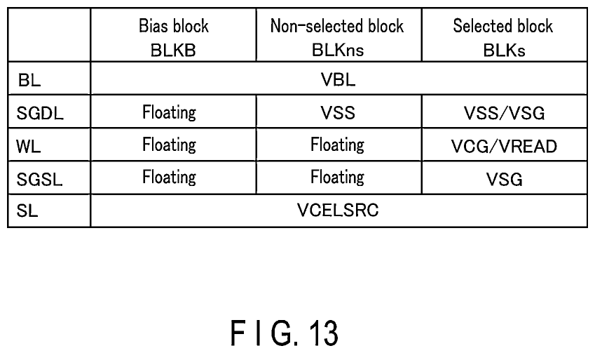

FIG. 13 shows voltages applied to some interconnects during data reading (data read operation) in the memory device of the first embodiment.

During data reading, the driver circuit SGDdr coupled to the selected string unit SUs outputs the read selection voltage VSG. The driver circuit SGDdr coupled to the non-selected string unit SU outputs the ground voltage VSS.

During data reading, the driver circuit CGdrv outputs the read voltage VCG or the read pass voltage VREAD.

During data reading, the driver circuit SGSdr outputs the program selection voltage VSGS.

The source line SL receives the read bias voltage VCELSRC by the driver 15. Each of the bit lines BL receives the read bias voltage VBL by the sense amplifier 17.

The bias block BLKB is required not to participate in the data reading and not to hinder the data reading in the selected block BLKs. For this purpose, during data reading, each of the select gate lines SGDL, each of the word lines WL, and the select gate line SGSL of the bias block BLKB are electrically floating. Since the select gate lines SGDL and SGSL and the word line WL of the bias block BLKB are electrically floating, the select gate transistors DT and ST and the memory cell transistor MT of the bias block BLKB are off.

The block decoder 111 coupled to any non-selected block BLKns is in an inactive state. Therefore, in each of the non-selected blocks BLKns, each of the select gate lines SGDL receives the ground voltage VSS, and each of the word lines WL and the select gate line SGSL are electrically floating. Therefore, the select gate transistors DT and ST and the memory cell transistor MT of the non-selected block BLKns are off.

On the other hand, the selected block BLKs receives voltages from the driver circuits SGDdr, CGdr, and SGSdr via the block decoder 111 coupled to the selected block BLKs. Therefore, the select gate line SGDL of the selected block BLKs receives the ground voltage VSS or the read selection voltage VSG, and the select gate line SGSL of the selected block BLKs receives the read selection voltage VSG. In addition, the word line WL of the selected block BLKs receives the read voltage VCG or the read pass voltage VREAD.

By applying the voltages as described above, data reading is performed to the cell unit CU that is subject to data reading of the selected block BLKs. By receiving the read selection voltage VSG, the select gate transistors DT and ST of the selected NAND string NS of the selected block BLKs are on. Further, by receiving the read pass voltage VREAD, the memory cell transistors MT of the cell units CU other than the cell unit CU that is subject to data reading are on. By receiving the read voltage VCG, the memory cell transistor MT having a threshold voltage of a magnitude less than the read voltage VCG in the cell unit CU that is subject to data reading is turned on. As a result, in the NAND string NS including the memory cell transistor MT having the threshold voltage of less than the read voltage VCG, the current flows from the bit line BL to the source line SL. On the other hand, even if the read voltage VCG is received, the memory cell transistor MT having a threshold voltage of a magnitude equal to or higher than the read voltage VCG in the cell unit CU that is subject to data reading remains off. As a result, in the NAND string NS including the memory cell transistor MT having the threshold voltage equal to or higher than the read voltage VCG, the flow of the current from the bit line BL to the source line SL is suppressed or prevented. Based on whether or not this current flows, the sense amplifier determines the data stored in the cell unit CU that is subject data reading.

### 1.3. Advantages (Advantageous Effects)

According to the first embodiment, it is possible to provide a memory device having a smaller area as described below.

For data erasing, it is necessary to inject holes into each semiconductor of the NAND string. For this purpose, it is necessary to increase the voltage at one end and/or the other end of the NAND string. One end of the NAND string is coupled to the source line, and the other end of the NAND string is coupled to the bit line. The source line is commonly coupled to the plurality of NAND strings. Therefore, the voltage at one end of the plurality of NAND strings can be increased by increasing the voltage of a single source line. Therefore, it is relatively easy to generate holes by increasing the voltage of the source line.

To more efficiently inject holes, injection of holes can be performed using a voltage rise at the other end of the NAND string. For that purpose, the voltage of the bit line needs to be raised. In the memory device, a plurality of independent bit lines is provided. For this reason, in charging the bit line, it is necessary to provide a driver circuit for charging the bit line for each bit line. However, since a large number of bit lines are provided, providing a driver circuit for each bit line may increase the area of the memory device.

According to the first embodiment, the bias block BLKB is provided. The bias block BLKB is not used for storing data. Instead, during data erasing, the select gate lines SGDL and SGSL and the word line WL of the bias block BLKB receive the erase voltage transfer voltage VERAH. As a result, the NAND string NS of the bias block BLKB can transfer the erase voltage VERA during data erasing. Then, during data erasing, the source line SL receives the erase voltage VERA. The erase voltage VERA of the source line SL is transferred through the NAND string NS of the bias block BLKB in a state in which the erase voltage VERA can be transferred. As a result, each of the bit lines BL is charged by the erase voltage VERA via the bias block BLKB. Therefore, it is not necessary to provide a driver circuit for charging the erase voltage VERA for each of the bit lines BL. Therefore, efficient hole injection using the bit line BL can be performed, and a memory device having a small area can be provided.

### 1.4. Modification

Although an example in which both the BL-side GIDL current and the SL-side GIDL current are used is described, only the BL-side GIDL current may be used. In addition, only the SL-side GIDL current may be used. In this case, the region including an end on a side (upper side) of the conductor 27 of a set of the semiconductor 51 and the conductor 25 is not doped with phosphorus as an impurity.

Referring to FIGS. 9, 11, and 12, an example in which the select gate lines SGDL and SGSL and the word line WL of the bias block BLKB are floated in data erasing, data writing, and data reading is described. During one or more of data erasing, data writing, and data reading, one or more of the select gate lines SGDL and SGSL and the word line WL of the bias block BLKB may receive the ground voltage VSS.

An example in which the GIDL current is used for data erasing is described. Data erasing is not limited to the use of the GIDL current. In this case, the conductor 21 has a p-type conductivity type, and contains or is made of boron-doped silicon, for example. As a result, holes independent of the GIDL current are injected into the semiconductor 51 of the selected block BLKs by the application of the voltage described above with reference to FIG. 9. In addition, holes independent of the GIDL current are injected into the semiconductor 51 of the selected block BLKs from the bit line BL receiving the erase voltage VERA via the bias block BLKB.

In each NAND string NS, a plurality of select gate transistors ST may be provided between the source line SL and the memory cell transistor MT_0. In this case, a plurality of conductors 22 is provided. The distance D in the range containing the high-concentration impurity in the semiconductor 51 is longer than the distance from the interface with the conductor 21 to the upper surface of the lowermost conductor 22. As a result, the lowermost select gate transistor ST exclusively contributes to generation of the GIDL current, and the other select gate transistors ST function as switches.

In each NAND string NS, a plurality of select gate transistors DT may be provided between the bit line BL and the memory cell transistor MT_n-1. In this case, a plurality of conductors 24 is provided. Then, the distance D in the range containing the high-concentration impurity in the semiconductor 51 is longer than the distance from the upper surface of the conductor 25 to the lower surface of the uppermost conductor 24. As a result, the uppermost select gate transistor DT exclusively contributes to generation of the GIDL current, and the other select gate transistors DT function as switches.

Referring to FIG. 5, an example in which a single driver circuit BLKBdr is provided and the single driver circuit BLKBdr drives all the select gate lines SGDL, all the word lines WL, and the select gate lines SGSL of the bias block BLKB is described above. The select gate line SGDL, the word line WL, and the select gate line SGSL of the bias block BLKB may be driven by a plurality of driver circuits BLKBdr. In this case, the set of the select gate line SGDL, the word line WL, and the select gate line SGSL of the bias block BLKB is divided into a plurality of groups, and each group is coupled to a single driver circuit BLKBdr. Then, all the driver circuits BLKBdr output the erase voltage transfer voltage VERAH during data erasing.

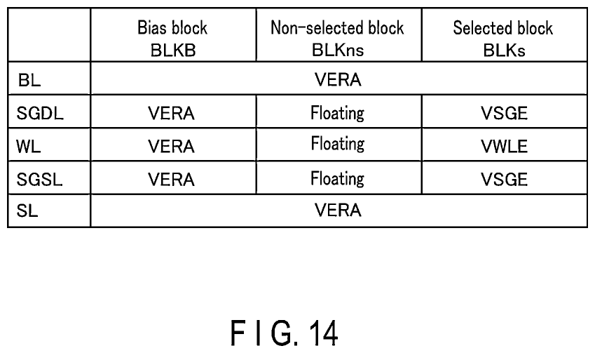

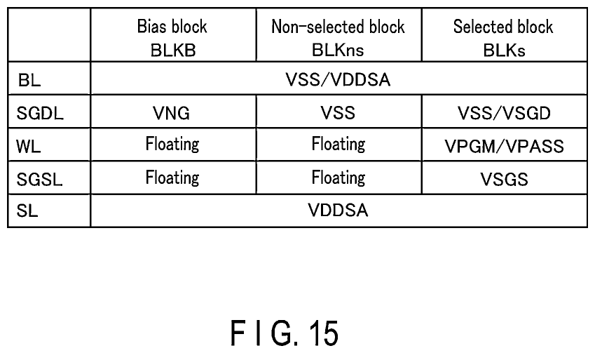

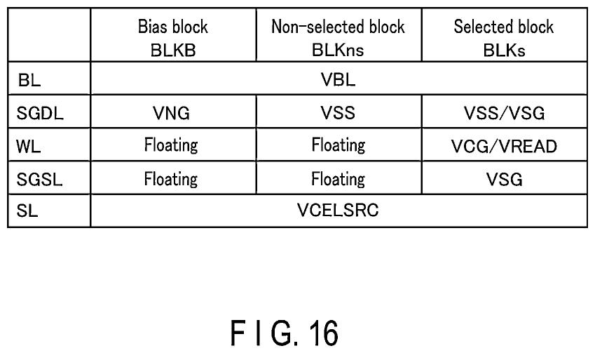

The select gate transistors DT and ST and the memory cell transistor MT of the bias block BLKB may be of a normally-on type. Examples of the application of the voltage in such a case are shown in FIGS. 14, 15, and 16. FIG. 14 shows voltages applied to some interconnects during data erasing in the memory device according to a modification of the first embodiment. FIG. 15 shows voltages applied to some interconnects during data writing in the memory device according to the modification of the first embodiment. FIG. 16 shows voltages applied to some interconnects during data reading in the memory device according to the modification of the first embodiment. Hereinafter, differences from the embodiments described above with reference to FIGS. 10, 12, and 13 will be mainly described.

As shown in FIG. 14, during data erasing, all the select gate lines SGDL, all the word lines WL, and the select gate lines SGSL of the bias block BLKB receive the erase voltage VERA from the driver circuit BLKBdr. Since the select gate transistors DT and ST and the memory cell transistor MT of the bias block BLKB are of the normally-on type, the erase voltage VERA can be transferred by the application of the erase voltage VERA.

As shown in FIG. 15, during data writing, the select gate line SGDL of the bias block BLKB receives the voltage VNG. The voltage VNG has a negative magnitude and has a magnitude capable of maintaining the select gate transistor DT off by being applied to the normally-on type select gate transistor DT. The voltage VNG is generated by the voltage generator 14 and supplied by the driver circuit SGDdr. By receiving the voltage VNG at the gate, the select gate transistor DT is off during data writing. Therefore, the current is suppressed or prevented from flowing through the select gate transistor DT, and eventually, the bias block BLKB is suppressed or prevented from hindering data writing.

As shown in FIG. 16, during data reading, the select gate line SGDL of the bias block BLKB receives the voltage VNG. By receiving the voltage VNG at the gate, the select gate transistor DT is off during data reading. Therefore, the current is suppressed or prevented from flowing through the select gate transistor DT, and eventually, the bias block BLKB is suppressed or prevented from hindering data reading.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A memory device comprising:
a first interconnect;
a second interconnect;
a first string having one end coupled to the first interconnect and another end coupled to the second interconnect, the first string including a first memory cell transistor;
a second string having one end coupled to the first interconnect and another end coupled to the second interconnect, the second string including a second memory cell transistor;
a first power supply line coupled to a gate of the first memory cell transistor via a first transistor and coupled to a gate of the second memory cell transistor via a second transistor;
a third string having one end coupled to the first interconnect and another end coupled to the second interconnect, the third string including a third memory cell transistor; and
a second power supply line coupled to a gate of the third memory cell transistor and applies a voltage different from that of the first power supply line during data erasing.

2. The memory device according to claim 1, wherein
the first string further includes a first select transistor between the first memory cell transistor and the first interconnect and a second select transistor between the first memory cell transistor and the second interconnect,
a first voltage is applied to the second interconnect,
a second voltage higher than the first voltage is applied to the second power supply line,
a third voltage lower than the first voltage is applied to a gate of the first select transistor and a gate of the second select transistor, and
a fourth voltage lower than the first voltage is applied to the gate of the first memory cell transistor.

3. The memory device according to claim 2, wherein
a fifth voltage is applied to the first interconnect, the fifth voltage being lower than the first voltage, the second voltage, and the third voltage,
a sixth voltage higher than the fifth voltage is applied to the second interconnect,
a seventh voltage higher than the fifth voltage is applied to the gate of the first select transistor,
an eighth voltage higher than the fifth voltage and lower than the second voltage is applied to the gate of the first memory cell transistor, and
the second power supply line is electrically floated or applied with the fifth voltage.

4. The memory device according to claim 2, wherein
a ninth voltage is applied to the first interconnect,
a tenth voltage lower than the ninth voltage is applied to the second interconnect,
an eleventh voltage is applied to the gate of the first select transistor and the gate of the second select transistor,
a twelfth voltage is applied to the gate of the first memory cell transistor, and
the second power supply line is electrically floated or applied with a fifth voltage lower than the tenth voltage.

5. The memory device according to claim 1, wherein
the third string further includes a third select transistor between the third memory cell transistor and the first interconnect and a fourth select transistor between the third memory cell transistor and the second interconnect, and
a gate of a third select transistor and a gate of the fourth select transistor are coupled to the second power supply line.

6. The memory device according to claim 5, wherein
the first string further includes a first select transistor between the first memory cell transistor and the first interconnect and a second select transistor between the first memory cell transistor and the second interconnect,
a first voltage is applied to the second interconnect,
a second voltage higher than the first voltage is applied to the second power supply line,
a third voltage lower than the first voltage is applied to a gate of the first select transistor and a gate of the second select transistor, and
a fourth voltage lower than the first voltage is applied to the gate of the first memory cell transistor.

7. The memory device according to claim 6, wherein
a fifth voltage is applied to the first interconnect, the fifth voltage being lower than the first voltage, the second voltage, and the third voltage,
a sixth voltage higher than the fifth voltage is applied to the second interconnect,
a seventh voltage higher than the fifth voltage is applied to the gate of the first select transistor,
an eighth voltage higher than the fifth voltage and lower than the second voltage is applied to the gate of the first memory cell transistor, and
the second power supply line is electrically floated or applied with the fifth voltage.

8. The memory device according to claim 6, wherein
a ninth voltage is applied to the first interconnect,
a tenth voltage lower than the ninth voltage is applied to the second interconnect,
an eleventh voltage is applied to the gate of the first select transistor and the gate of the second select transistor,
a twelfth voltage is applied to the gate of the first memory cell transistor, and
the second power supply line is electrically floated or applied with a fifth voltage lower than the tenth voltage.

9. The memory device according to claim 1, wherein
the third string includes a plurality of third memory cell transistors including the third memory cell transistor and coupled in series, and
each gate of the plurality of third memory cell transistors is coupled to the second power supply line.

10. The memory device according to claim 9, wherein
the first string further includes a first select transistor between the first memory cell transistor and the first interconnect and a second select transistor between the first memory cell transistor and the second interconnect,
a first voltage is applied to the second interconnect,
a second voltage higher than the first voltage is applied to the second power supply line,
a third voltage lower than the first voltage is applied to a gate of the first select transistor and a gate of the second select transistor, and
a fourth voltage lower than the first voltage is applied to the gate of the first memory cell transistor.

11. The memory device according to claim 10, wherein
a fifth voltage is applied to the first interconnect, the fifth voltage being lower than the first voltage, the second voltage, and the third voltage,
a sixth voltage higher than the fifth voltage is applied to the second interconnect,
a seventh voltage higher than the fifth voltage is applied to the gate of the first select transistor,
an eighth voltage higher than the fifth voltage and lower than the second voltage is applied to the gate of the first memory cell transistor, and
the second power supply line is electrically floated or applied with the fifth voltage.

12. The memory device according to claim 10, wherein
a ninth voltage is applied to the first interconnect,
a tenth voltage lower than the ninth voltage is applied to the second interconnect,
an eleventh voltage is applied to the gate of the first select transistor and the gate of the second select transistor,
a twelfth voltage is applied to the gate of the first memory cell transistor, and
the second power supply line is electrically floated or applied with a fifth voltage lower than the tenth voltage.

13. A memory device comprising:
a first interconnect;
a second interconnect;
a first select transistor coupled to the first interconnect;
a second select transistor coupled to the second interconnect;
a first memory cell transistor between the first select transistor and the second select transistor;
a first driver coupled to one of a gate of the first select transistor, a gate of the second select transistor, and a gate of the first memory cell transistor via a first transistor;
a third select transistor coupled to the first interconnect;
a fourth select transistor coupled to the second interconnect;
a second memory cell transistor between the third select transistor and the fourth select transistor; and
a second driver coupled to one of a gate of the third select transistor, a gate of the fourth select transistor, and a gate of the second memory cell transistor without interposing a transistor.
